(19) United States
(12) Patent Application Publication
(10) Pub. No.: US 2025/0316657 A1
(43) Pub. Date: Oct. 9, 2025

(54) SEMICONDUCTOR DEVICE

(71) Applicant: Mitsubishi Electric Corporation, Tokyo (JP)

(72) Inventors: Kazuhiro NISHIMURA, Fukuoka (JP); Hideo KOMO, Tokyo (JP)

(73) Assignee: Mitsubishi Electric Corporation, Tokyo (JP)

(21) Appl. No.: 18/872,707

(22) PCT Filed: Oct. 12, 2022
(86) PCT No.: PCT/JP2022/038032

§ 371 Date: Dec. 6, 2024

(51) Int. Cl. H01L 25/16; H01L 23/00; H01L 23/34; H01L 23/60; H01L 23/64; H10D 80/20

(52) U.S. Cl. CPC H01L 25/16; H01L 23/34; H01L 23/60; H01L 23/642; H01L 23/647; H01L 24/32; H01L 24/48; H01L 24/73; H01L 2224/32245; H01L 2224/48137; H01L 2224/48245; H01L 2224/73215; H01L 2224/73265; H01L 2924/13091; H10D 80/251

(57) ABSTRACT

A semiconductor device includes: a base plate; semiconductor elements; and wiring elements disposed adjacent to the respective semiconductor elements on the base plate. A diode sensing a temperature of an adjacent one of the semiconductor elements is disposed in each of the wiring elements. The wire pad of each of the wiring elements is disposed to face the wire pad of the adjacent semiconductor element. The diode of each of the wiring elements is disposed closer to the adjacent semiconductor element. The wire pad of each of the semiconductor elements is connected through a wire to the wire pad of the wiring element adjacent to the semiconductor element.

### BACKGROUND OF THE INVENTION

### Field of the Invention

The present disclosure relates to a semiconductor device.

### Description of the Background Art

Semiconductor devices mounted on power converters such as inverters employ a structure of connecting a plurality of semiconductor elements in parallel and driving the semiconductor elements to pass a large current. For example, Patent Document 1 discloses, in a semiconductor device including a plurality of semiconductor elements, a structure including a wiring element separately from the semiconductor elements as a means for maximizing an effective area of the semiconductor elements.

### PRIOR ART DOCUMENT

### Patent Document

Patent Document 1: WO2020/110170

### SUMMARY

### Problem to Be Solved by the Invention

Under the technology described in Patent Document 1, disposing the wiring element in the center of a base plate and disposing the plurality of semiconductor elements to surround the wiring element make a wirelength from each of the semiconductor elements to the wiring element uniform. This causes constraints in disposing the semiconductor elements and the wiring element and routing external electrodes. Thus, a problem of low layout flexibility has occurred.

Moreover, monitoring overheating and an overcurrent condition in the semiconductor device requires that each of the semiconductor elements should include a temperature sensing element that senses the temperature of the semiconductor element. Thus, maximizing an effective area of all the semiconductor elements has been difficult. When one of the semiconductor elements includes a temperature sensing element, only the temperature of the semiconductor element including the temperature sensing element can be sensed. Thus, a semiconductor element that senses the temperature cannot be selected in consideration of a heat distribution in the semiconductor device.

The present disclosure has an object of providing a technology that can improve the layout flexibility in a semiconductor device including a plurality of semiconductor elements, sense the temperature of a semiconductor element in consideration of a heat distribution in the semiconductor device, and maximize an effective area of the semiconductor elements.

### Means to Solve the Problem

A semiconductor device according to the present disclosure includes: a base plate; a plurality of semiconductor elements mounted on the base plate, each of the semiconductor elements including a wire pad; and a plurality of wiring elements disposed adjacent to the respective semiconductor elements on the base plate, each of the wiring elements including a wire pad, wherein a temperature sensor that senses a temperature of an adjacent one of the semiconductor elements is disposed in each of the wiring elements, the wire pad of each of the wiring elements is disposed to face the wire pad of the adjacent one of the semiconductor elements, the temperature sensor of each of the wiring elements is disposed closer to the adjacent one of the semiconductor elements, and the wire pad of each of the semiconductor elements is connected through a wire to the wire pad of a corresponding one of the wiring elements adjacent to the semiconductor element.

### Effects of the Invention

The plurality of the wiring elements are disposed adjacent to the respective semiconductor elements, and the wire pad of each of the wiring elements is disposed to face the wire pad of the adjacent semiconductor element according to the present disclosure. Thus, the semiconductor element and the wiring element can be wired with a given wirelength or less without any interference. This improves the layout flexibility of the semiconductor device more than conventional ones, without requiring disposing the semiconductor elements to surround the wiring element.

Furthermore, since a temperature sensor for each of the semiconductor elements is disposed in a corresponding one of the wiring elements, the semiconductor element that senses the temperature can be selected in consideration of a heat distribution in the semiconductor device.

The temperature sensor of each of the wiring elements is disposed closer to the adjacent semiconductor element. Thus, the temperature sensor exhibits better thermal bondability with the semiconductor element, and has better precision of sensing the temperature of the semiconductor element. Since this can omit a temperature sensor from the semiconductor elements, an effective area of the semiconductor elements can be maximized.

The object, features, aspects, and advantages of this disclosure will become more apparent from the following detailed description and the accompanying drawings.

### BRIEF DESCRIPTION OF THE DRAWINGS

FIG. 1 is a top view of a semiconductor device according to Embodiment 1.

FIG. 2 is a cross-sectional view of the semiconductor device according to Embodiment 1.

FIG. 3 is a top view of a wiring element included in the semiconductor device according to Embodiment 1.

FIG. 4 is a cross-sectional view of a line A-A in FIG. 3.

FIG. 5 is a cross-sectional view of a line B-B in FIG. 3.

FIG. 6 is an equivalent circuit diagram of the semiconductor device according to Embodiment 1.

FIG. 7 is a top view of a semiconductor device according to Embodiment 2.

FIG. 8 is a top view of a wiring element included in the semiconductor device according to Embodiment 2.

FIG. 9 is an equivalent circuit diagram of the semiconductor device according to Embodiment 2.

FIG. 10 is a top view of a semiconductor device according to Embodiment 3.

FIG. 11 is a top view of a wiring element included in the semiconductor device according to Embodiment 3.

FIG. 12 is a cross-sectional view of a line C-C in FIG. 11.

FIG. 13 is an equivalent circuit diagram of a semiconductor device and a control board when the control board includes a high-voltage diode.

FIG. 14 is an equivalent circuit diagram of the semiconductor device according to Embodiment 3 and a control board when the semiconductor device includes high-voltage diodes.

FIG. 15 is a top view of a wiring element included in a semiconductor device according to Embodiment 4.

FIG. 16 is an equivalent circuit diagram of a wiring element included in the semiconductor device according to Embodiment 4.

FIG. 17 is a top view of a semiconductor device according to Embodiment 5.

FIG. 18 is a cross-sectional view of the semiconductor device according to Embodiment 5.

FIG. 19 is a top view of a semiconductor device according to Embodiment 6.

### DESCRIPTION OF THE PREFERRED EMBODIMENTS

### Embodiment 1

### Overall Structure of Semiconductor Device

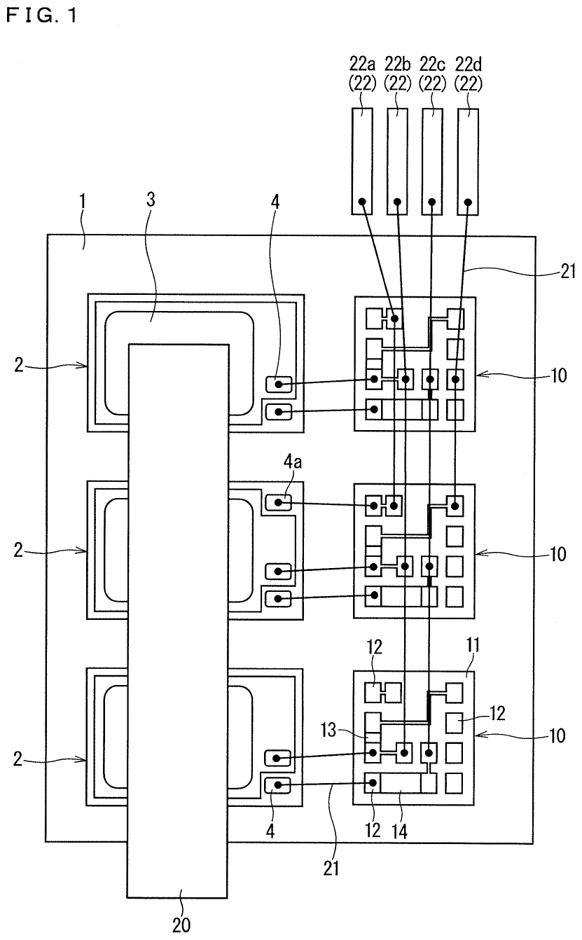

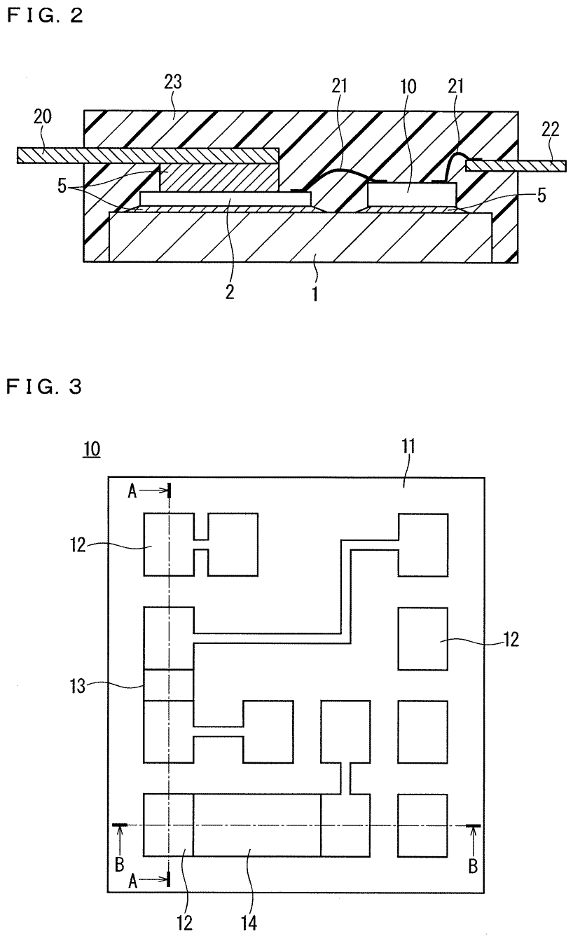

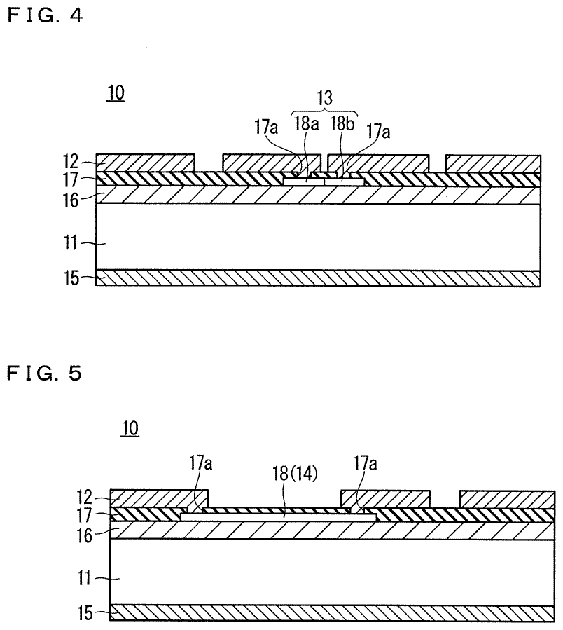

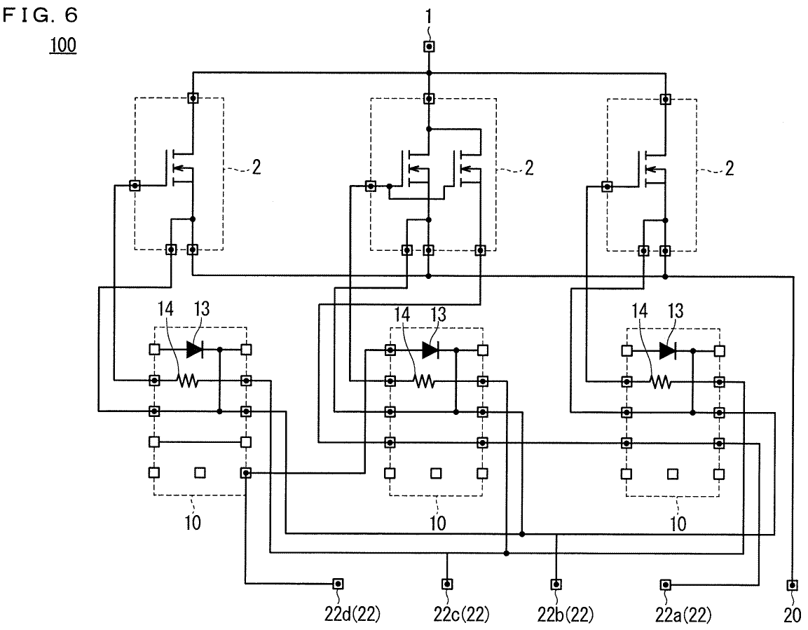

Embodiment 1 will be hereafter described with reference to the drawings. FIG. 1 is a top view of a semiconductor device 100 according to Embodiment 1. FIG. 2 is a cross-sectional view of the semiconductor device 100 according to Embodiment 1. FIG. 3 is a top view of a wiring element 10 included in the semiconductor device 100 according to Embodiment 1. FIG. 4 is a cross-sectional view of a line A-A in FIG. 3. FIG. 5 is a cross-sectional view of a line B-B in FIG. 3. FIG. 6 is an equivalent circuit diagram of the semiconductor device 100 according to Embodiment 1. In FIG. 2, an extension direction 20 of an external electrode 20 and a control terminal 22 has been changed to facilitate viewing of a connectivity relationship of components.

As illustrated in FIGS. 1 and 2, the semiconductor device 100 includes a base plate 1, a plurality of (e.g., three) semiconductor elements 2, a plurality of (e.g., three) wiring elements 10, the external electrode 20, and four control terminals 22.

The base plate 1 is made of a metal such as Cu and Al as a main material.

Furthermore, the base plate 1 is formed into a rectangle in a top view, and functions as a drain terminal. The base plate 1 may be hereinafter referred to as a drain terminal 1.

The plurality of semiconductor elements 2 are mounted on the base plate 1 by bonding back surfaces thereof through a conductive bonding material 5 such as solder, an Ag paste material, or a Cu paste material. Each of the semiconductor elements 2 is a metal-oxide-semiconductor field effect transistor (MOSFET). The surface electrode of each of the semiconductor elements 2 is divided into two regions, namely, a region in which a main terminal electrode 3 that passes a main current is disposed, and a region in which wire pads 4 for transmitting a driving voltage signal, a temperature signal, and an overcurrent signal of the semiconductor element 2 are disposed. The region in which the wire pads 4 are disposed is to the right in FIG. 1 (closer to the wiring element 10), and the region in which the main terminal electrode 3 is disposed is to the left in FIG. 1.

The main terminal electrode 3 is bonded to the external electrode 20 through the conductive bonding material 5, and each of the wire pads 4 is connected to a wire pad 12 of the adjacent wiring element 10. Each of the semiconductor elements 2 may be a semiconductor element such as an insulated-gate bipolar transistor (IGBT) or a reverse conducting IGBT except a MOSFET.

A plurality of the wiring elements 10 are disposed adjacent to the respective semiconductor elements 2 on the base plate 1. The plurality of the wiring elements 10 are disposed on the base plate 1 by bonding the back surfaces thereof through the conductive bonding material 5. In each of the wiring elements 10, a resistor 14 that suppresses an oscillation operation of an adjacent one of the plurality of semiconductor elements 2, and a diode 13 functioning as a temperature sensor that senses the temperature of the adjacent semiconductor element 2 are disposed. The diode 13 of each of the wiring elements 10 is disposed closer to the adjacent semiconductor element 2.

The external electrode 20 is made of Cu, and is disposed on the main terminal electrodes 3 of the plurality of semiconductor elements 2 to connect the plurality of semiconductor elements 2. The main terminal electrode 3 functions as a source terminal, and the external electrode 20 disposed on the main terminal electrodes 3 also functions as a source terminal. The external electrode 20 may be referred to as a source terminal 20.

As illustrated in FIGS. 1 and 6, the plurality of semiconductor elements 2 are connected in parallel, and the plurality of wiring elements 10 are connected to the plurality of semiconductor elements 2 while being adjacent to the plurality of semiconductor elements 2.

The four control terminals 22 are terminals for inputting and outputting signals on controlling the semiconductor elements 2. The four control terminals 22 are a current sensing terminal 22a, a Kelvin source terminal 22b, a gate terminal 22c, and a temperature sensing anode terminal 22d. The control terminals 22 are connected to the semiconductor elements 2 through the wiring elements 10. In Embodiment 1, a current sensing scheme is employed as a short circuit detection scheme for detecting a short circuit state of the semiconductor elements 2.

### Structure of Wiring Element

Next, a structure of each of the wiring elements 10 will be described. As illustrated in FIGS. 3, 4, and 5, each of the wiring elements 10 includes a Si substrate 11 as a base material. A back electrode 15 made of Al, Ti, Ni, or Au is formed on the back surface of the Si substrate 11. The back surface of each of the wiring elements 10 is bonded to the base plate 1 through the conductive bonding material 5, similarly to the semiconductor elements 2.

A thermal oxide film 16 is formed on the front surface of the Si substrate 11. Passive elements such as the resistor 14 made of polycrystalline silicon (poly-Si) 18, and the diode 13 made of polycrystalline silicon (p-type) 18a and polycrystalline silicon (n-type) 18b are formed on the thermal oxide film 16. An insulating interlayer film 17 is formed on the thermal oxide film 16 and the polycrystalline silicon 18, the polycrystalline silicon 18a, and the polycrystalline silicon 18b to insulate the resistor 14 from signal terminals of the diode 13 on the front surface side of the Si substrate 11. Furthermore, the wire pads 12 each functioning as a surface electrode made of Al are formed on the insulating interlayer film 17.

A contact portion 17a for electrically connecting the resistor 14 and the diode 13 to the wire pad 12 functioning as a surface electrode is provided as a part of the insulating interlayer film 17. As illustrated in FIG. 1, each of the wire pads 4 of the semiconductor elements 2 is connected to the control terminal 22 through the wiring element 10. The wiring element 10 has a function of relaying wires. As illustrated in FIGS. 1, 4, and 5, the wire pad 12 for connecting the wire pad 4 of the semiconductor element 2 to the control terminal 22 through a wire 21 is disposed on the front surface of the wiring element 10. The wire pad 12 of each of the wiring elements 10 is disposed to face the wire pad 4 of the adjacent semiconductor element 2, and the wire pads 12 are disposed in other portions. The wire pad 4 of each of the semiconductor elements 2 is connected through the wire 21 to the wire pad 12 of the wiring element 10 adjacent to the semiconductor element 2.

A sealant (not illustrated) made of, for example, an epoxy resin seals an interior of the semiconductor device 100 to provide electrical isolation.

### Advantages

Next, advantages of the semiconductor device 100 according to Embodiment 1 will be described in comparison with the technology described in Patent Document 1 (WO2020/110170).

Under the technology described in Patent Document 1, disposing the wiring element in the center of the base plate and disposing the semiconductor elements to surround the wiring element make the wirelength from each of the semiconductor elements to the wiring element uniform. This causes constraints in disposing the semiconductor elements and the wiring element and routing the external electrodes. Thus, a problem of low layout flexibility has occurred.

In contrast, the semiconductor device 100 according to Embodiment 1 includes the base plate 1, the plurality of semiconductor elements 2 each including the wire pads 4, and the plurality of wiring elements 10 being disposed adjacent to the respective semiconductor elements 2 on the base plate 1 and each including the wire pads 12. In each of the wiring elements 10, the diode 13 is disposed as a temperature sensor that senses the temperature of an adjacent one of the plurality of semiconductor elements 2. The wire pad 12 of each of the wiring elements 10 is disposed to face the wire pad 4 of the adjacent semiconductor element 2. The diode 13 functioning as a temperature sensor of each of the wiring elements 10 is disposed closer to the adjacent semiconductor element 2. The wire pad 4 of each of the semiconductor elements 2 is connected through the wire 21 to the wire pad 12 of the wiring element 10 adjacent to the semiconductor element 2.

Since the plurality of wiring elements 10 are disposed adjacent to the respective semiconductor elements 2, and the wire pad 12 of each of the wiring elements 10 is disposed to face the wire pad 4 of the adjacent semiconductor element 2, the semiconductor element 2 and the wiring element 10 can be wired with a given wirelength or less without any interference. This improves the layout flexibility of the semiconductor device 100 more than conventional ones, without requiring disposing the semiconductor elements 2 to surround the wiring element 10.

Furthermore, since the diode 13 is disposed in each of the wiring elements 10 as a temperature sensor for a corresponding one of the semiconductor elements 2, the semiconductor element 2 that senses the temperature can be selected in consideration of a heat distribution in the semiconductor device 100.

The diode 13 functioning as a temperature sensor of each of the wiring elements 10 is disposed closer to the adjacent semiconductor element 2. Thus, the diode 13 exhibits better thermal bondability with the semiconductor element 2, and has better precision of sensing the temperature of the semiconductor element 2. Since this can omit a temperature sensor from the semiconductor elements 2, an effective area of the semiconductor elements 2 can be maximized.

When the plurality of semiconductor elements 2 are driven in parallel, variations in characteristics of the semiconductor elements 2 and stray inductance of main terminals and the wires 21 in the semiconductor device 100 cause a transient surge voltage and current deviation. This may lead to a malfunction and a break in the semiconductor elements 2. Typically, in order to suppress gate oscillation operations of the semiconductor elements 2 which are caused by a transient surge at turn off time, a balance resistor designed to suppress the oscillations is disposed on a gate line of the semiconductor element 2. Since the resistor 14 that suppresses an oscillation operation of the adjacent semiconductor element 2 is further disposed in each of the wiring elements 10 in Embodiment 1, a malfunction and a break in the semiconductor device 100 can be suppressed at low cost without requiring disposing a balance resistor in the semiconductor elements 2.

### Embodiment 2

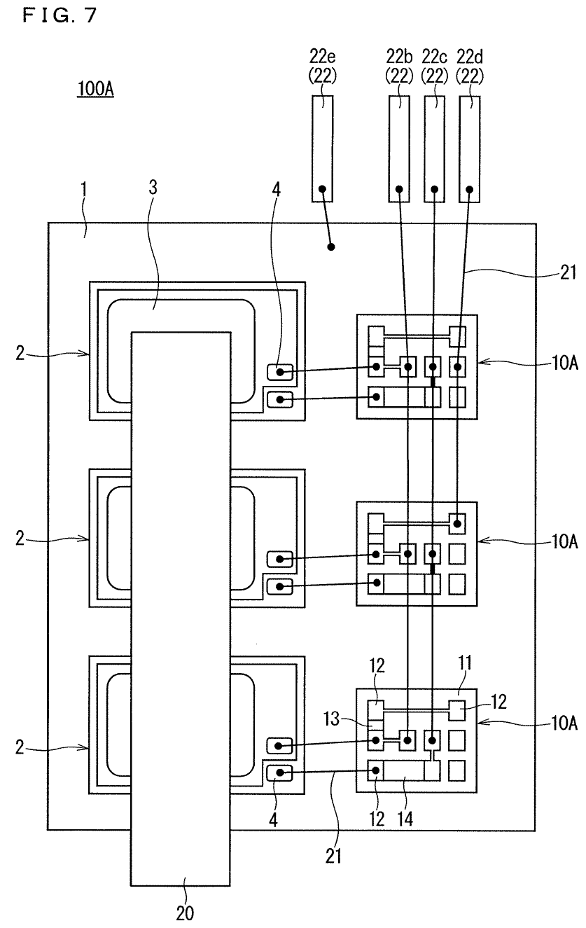

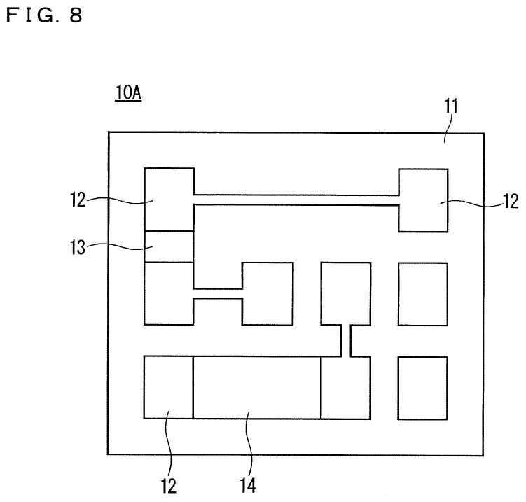

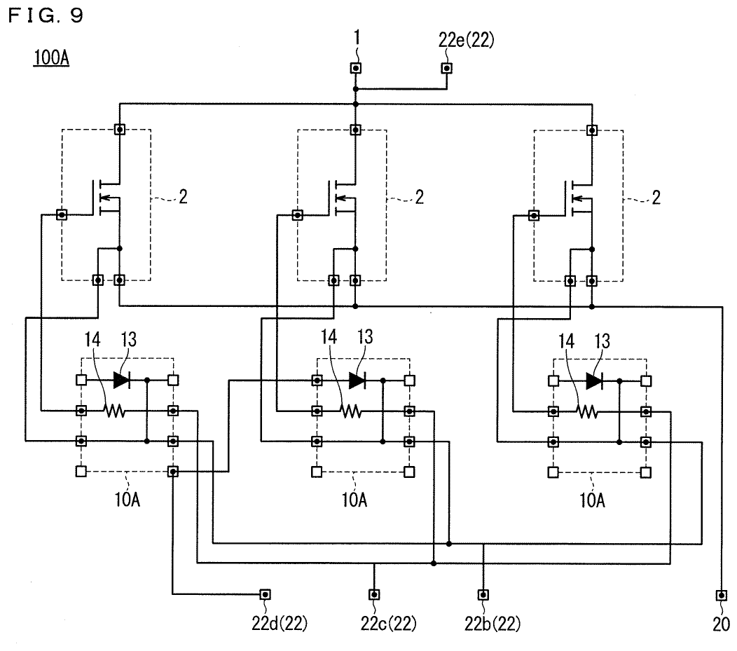

Next, a semiconductor device 100A according to Embodiment 2 will be described. FIG. 7 is a top view of the semiconductor device 100A according to Embodiment 2. FIG. 8 is a top view of a wiring element 10A included in the semiconductor device 100A according to Embodiment 2. FIG. 9 is an equivalent circuit diagram of the semiconductor device 100A according to Embodiment 2. In Embodiment 2, the same reference numerals are assigned to the same constituent elements described in Embodiment 1, and the description thereof will be omitted.

As illustrated in FIGS. 7, 8, and 9, the short circuit detection scheme for detecting a short circuit state of the semiconductor elements 2 has been changed from the current sensing scheme to a desaturation voltage detection scheme in Embodiment 2. Thus, a desaturation voltage detection output terminal 22e for externally extracting a desaturation voltage (a drain voltage) of each of the semiconductor elements 2 is disposed as the control terminal 22, instead of the current sensing terminal 22a (see FIG. 1). The desaturation voltage detection output terminal 22e is connected to the drain terminal 1. Changing the short circuit detection scheme from the current sensing scheme to the desaturation voltage detection scheme omits a current sensing element 4a formed in each of the semiconductor elements 2, and a current sensing path formed in each of the wiring elements 10 as illustrated in FIG. 1. Here, the current sensing path is a portion formed in the wiring element 10, in a path from the current sensing element 4a to the current sensing terminal 22a through the wire 21 and the wire pad 12 in FIG. 1.

As described above, the semiconductor device 100A according to Embodiment 2 further includes the control terminals 22 for inputting and outputting signals on controlling each of the semiconductor elements 2, and the control terminals 22 include the desaturation voltage detection output terminal 22e for externally extracting a drain voltage of each of the semiconductor elements 2.

Since the current sensing element 4a of each of the semiconductor elements 2 and the current sensing path of each of the wiring elements 10 can be omitted, the cost of the semiconductor device 100A can be reduced without impairing a function of protecting the semiconductor elements 2.

### Embodiment 3

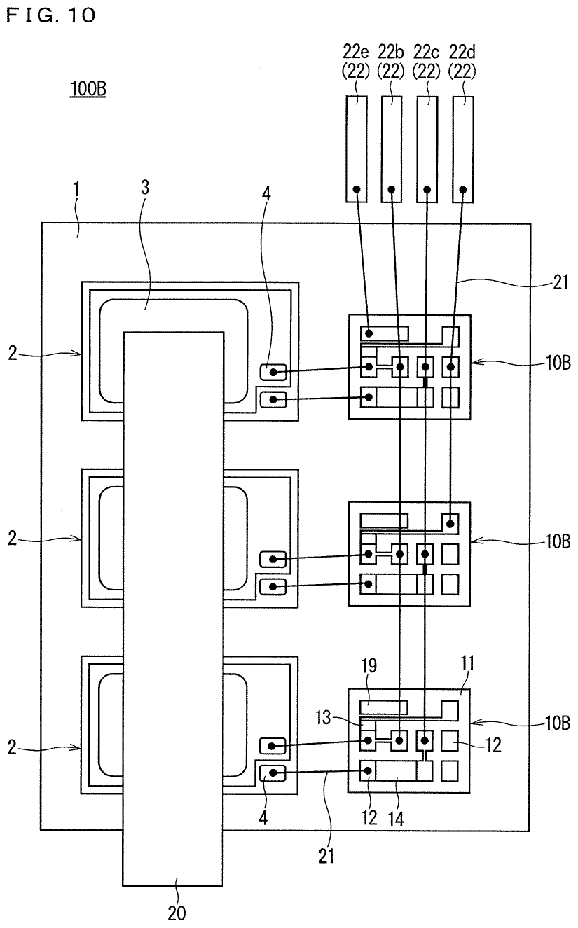

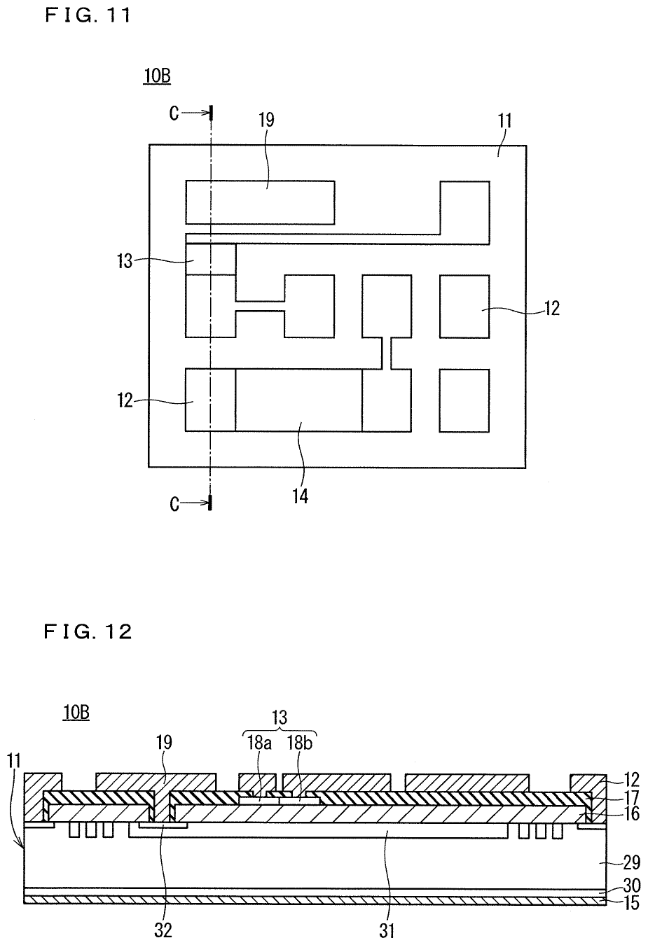

Next, a semiconductor device according to Embodiment 3 will be described. FIG. 10 is a top view of a semiconductor device 100B according to Embodiment 3. FIG. 11 is a top view of a wiring element 10B included in the semiconductor device 100B according to Embodiment 3. FIG. 12 is a cross-sectional view of a line C-C in FIG. 11. In Embodiment 3, the same reference numerals are assigned to the same constituent elements described in Embodiments 1 and 2, and the description thereof will be omitted.

As illustrated in FIGS. 10, 11, and 12, a high-voltage diode 19 that insulates the desaturation voltage detection output terminal 22e for externally extracting a drain voltage of the adjacent semiconductor element 2 is disposed in each of the wiring elements 10B in Embodiment 3. In the Si substrate 11, an N⁻ layer 29, an N⁺ layer 30, a P⁻ layer 31, and a P⁺ layer 32 are formed.

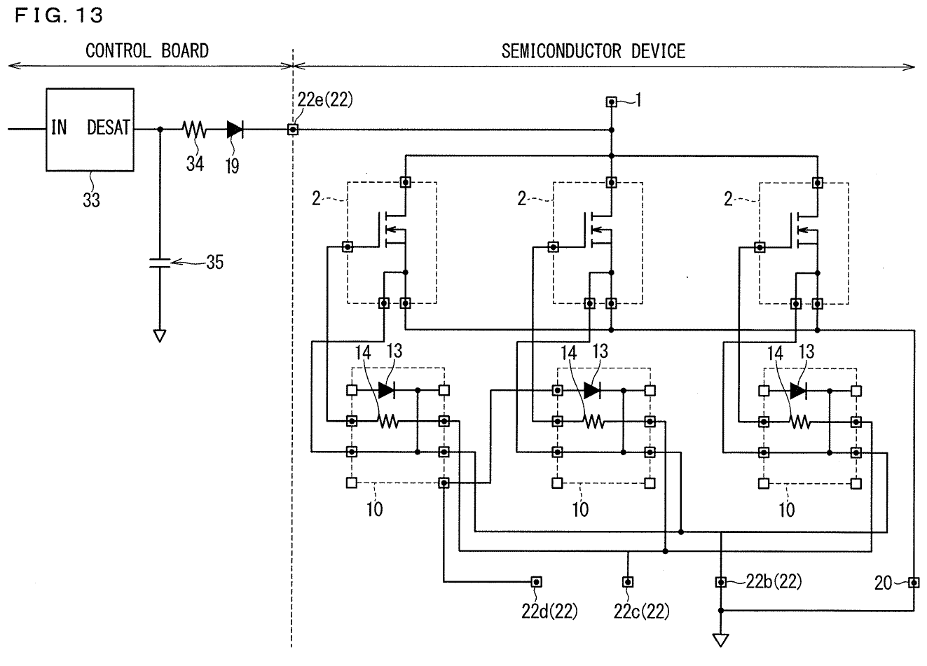

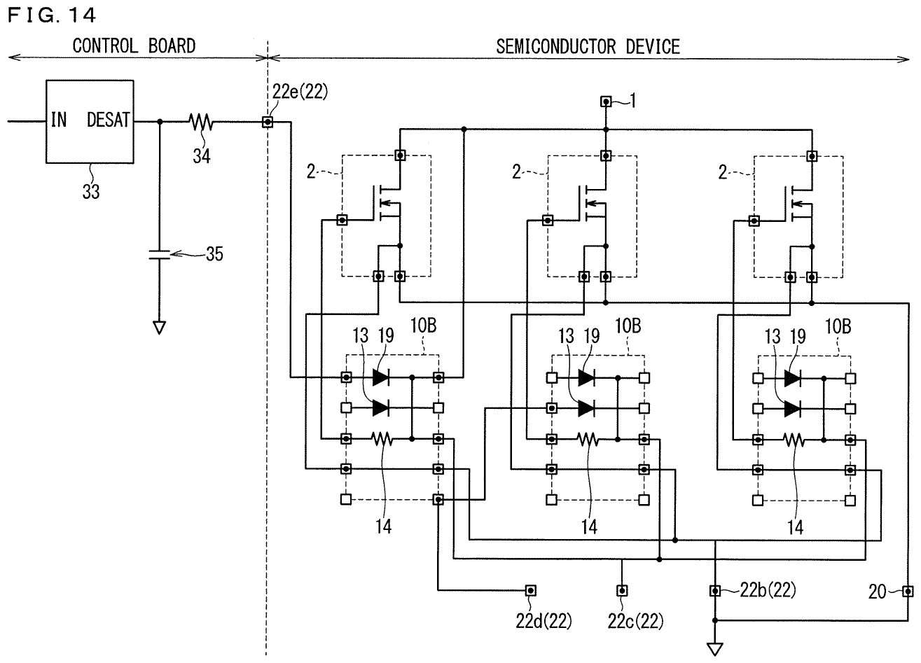

Next, advantages of disposing the high-voltage diode 19 in each of the wiring elements 10B will be described in comparison with disposing the high-voltage diode 19 in a control board for controlling a semiconductor device. FIG. 13 is an equivalent circuit diagram of the semiconductor device and the control board when the control board includes the high-voltage diode 19. FIG. 14 is an equivalent circuit diagram of the semiconductor device 100B according to Embodiment 3 and a control board when the semiconductor device 100B includes the high-voltage diodes 19.

As illustrated in FIG. 13, the control board includes the high-voltage diode 19 as well as a control IC 33, a resistor 34, and a capacitor 35, and a high-voltage line needs to be installed in a portion of the control board which is connected to the desaturation voltage detection output terminal 22e.

In contrast, when the high-voltage diode 19 is disposed in each of the wiring elements 10B as illustrated in FIG. 14, the desaturation voltage detection output terminal 22e is electrically insulated in the semiconductor device 100B. Since the control board need not include a high-voltage line, downsizing of the control board and improvement of the layout flexibility are expected.

Assuming that I_{CHG} denotes a charging current, R_{DESAT} denotes a value of the resistor 34, V_{F} denotes a forward voltage of the high-voltage diode 19, and V_{DS} denotes a desaturation voltage of the semiconductor element 2 that is an MOSFET, an overcurrent decision threshold V_{DESAT} of the control IC 33 is expressed by V_{DESAT}=I_{CHG}×R_{DESAT}+V_{F}+V_{DS}.

The desaturation voltage V_{DS} of the MOSFET has positive temperature characteristics in which the higher the temperature is, the larger the absolute value becomes.

Thus, the higher the environmental temperature is, the higher the overcurrent decision threshold V_{DESAT} becomes. The control IC 33 monitors the overcurrent decision threshold V_{DESAT}, and transitions to an overcurrent protection operation when the overcurrent decision threshold V_{DESAT} is higher than or equal to a given level. However, the monitoring range of the control IC 33 has a limitation. An excessive increase in the overcurrent decision threshold V_{DESAT} at high temperatures affects an operation temperature range of an overcurrent protection circuit.

Furthermore, disposing the high-voltage diode 19 in the vicinity of the semiconductor element 2 in each of the wiring elements 10B as illustrated in FIG. 14 increases the temperature of the high-voltage diodes 19 more than that in FIG. 13. The forward voltage V_{F} of the high-voltage diode 19 has negative temperature characteristics in which the higher the temperature is, the more the forward voltage decreases, and operates in a direction of canceling the desaturation voltage temperature characteristics of the MOSFET. This improves the precision of detecting the overcurrent decision threshold V_{DESAT}.

### Embodiment 4

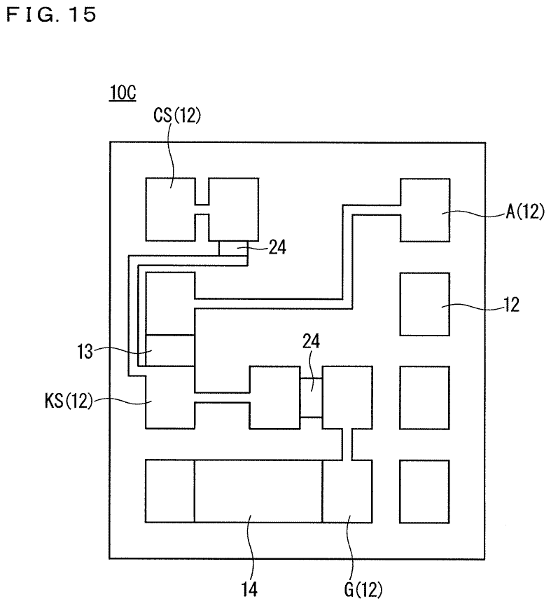

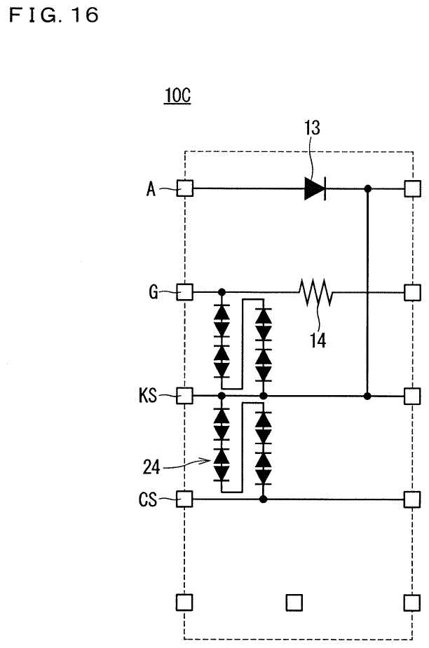

Next, a semiconductor device according to Embodiment 4 will be described. FIG. 15 is a top view of a wiring element 10C included in the semiconductor device according to Embodiment 4. FIG. 16 is an equivalent circuit diagram of the wiring element 10C included in the semiconductor device according to Embodiment 4. In Embodiment 4, the same reference numerals are assigned to the same constituent elements described in Embodiments 1 to 3, and the description thereof will be omitted.

In Embodiment 4, protection diodes 24 are added to Embodiment 1. Specifically, the protection diodes 24 that protect the adjacent semiconductor element 2 from electrostatic destruction are disposed in each of the wiring elements 10C as illustrated in FIGS. 15 and 16. Specifically, the protection diodes 24 are disposed between a gate terminal G and a Kelvin source terminal KS and between a current sensing terminal CS and the Kelvin source terminal KS in each of the wiring elements 10C. Here, the gate terminal G, the Kelvin source terminal KS, the current sensing terminal CS, and a temperature sensing anode terminal A in FIGS. 15 and 16 are connected through the wires 21 to the gate terminal 22c, the Kelvin source terminal 22b, the current sensing terminal 22a, and the temperature sensing anode terminal 22d, respectively, in FIG. 1.

Since this can suppress the electrostatic destruction of the semiconductor elements 2, the reliability and the assemblability of the semiconductor device will be improved.

### Embodiment 5

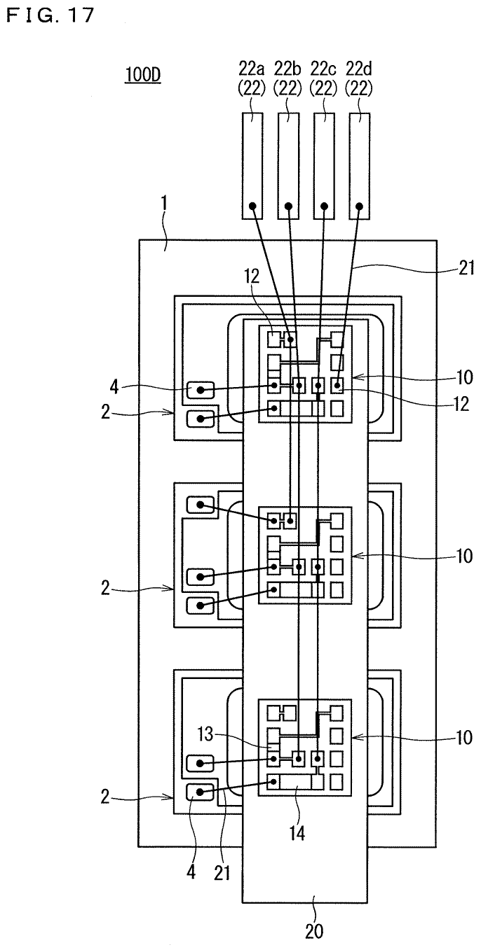

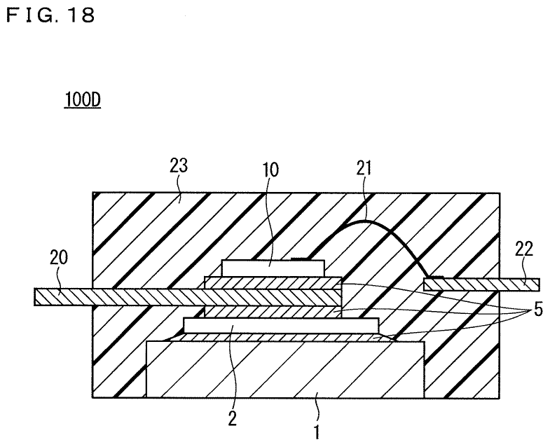

Next, a semiconductor device 100D according to Embodiment 5 will be described. FIG. 17 is a top view of the semiconductor device 100D according to Embodiment 5. FIG. 18 is a cross-sectional view of the semiconductor device 100D according to Embodiment 5. In Embodiment 5, the same reference numerals are assigned to the same constituent elements described in Embodiments 1 to 4, and the description thereof will be omitted.

As illustrated in FIGS. 17 and 18, the plurality of wiring elements 10 are disposed in portions corresponding to the respective semiconductor elements 2 on the external electrode 20 such that each of the wiring elements 10 is adjacent to and above a corresponding one of the semiconductor elements 2 through the external electrode 20 in Embodiment 5. The plurality of the wiring elements 10 are disposed on the external electrode 20 by bonding the back surfaces thereof through the conductive bonding material 5.

In each of the wiring elements 10, the resistor 14 that suppresses an oscillation operation of a corresponding one of the semiconductor elements 2 adjacent to and below the wiring element 10 through the external electrode 20, and the diode 13 functioning as a temperature sensor that senses the temperature of the semiconductor element 2 adjacent to and below the wiring element 10 through the external electrode 20 are disposed. The wire pad 12 of each of the wiring elements 10 is disposed to face the wire pad 4 of the semiconductor element 2 adjacent to and below the wiring element 10 through the external electrode 20, and the wire pads 12 are disposed in other portions. The diode 13 of each of the wiring elements 10 is disposed closer to the semiconductor element 2 adjacent to and below the wiring element 10 through the external electrode 20. The wire pad 4 of each of the semiconductor elements 2 is connected through the wire 21 to the wire pad 12 of a corresponding one of the wiring elements 10 adjacent to and above the semiconductor element 2.

As described above, the semiconductor device 100D according to Embodiment 5 can improve the layout flexibility, sense the temperature of the semiconductor element 2 in consideration of a heat distribution in the semiconductor device 100D, and maximize the effective area of the semiconductor elements 2, similarly to Embodiment 1. Furthermore, a malfunction and a break in the semiconductor device 100D can be suppressed at low cost without requiring disposing a balance resistor in the semiconductor elements 2.

Since the plurality of wiring elements 10 are disposed in the portions corresponding to the respective semiconductor elements 2 on the external electrode 20 such that each of the wiring elements 10 is adjacent to and above a corresponding one of the semiconductor elements 2 through the external electrode 20, the area of the base plate 1 can be reduced more than that according to Embodiment 1. This can downsize the semiconductor device 100D.

### Embodiment 6

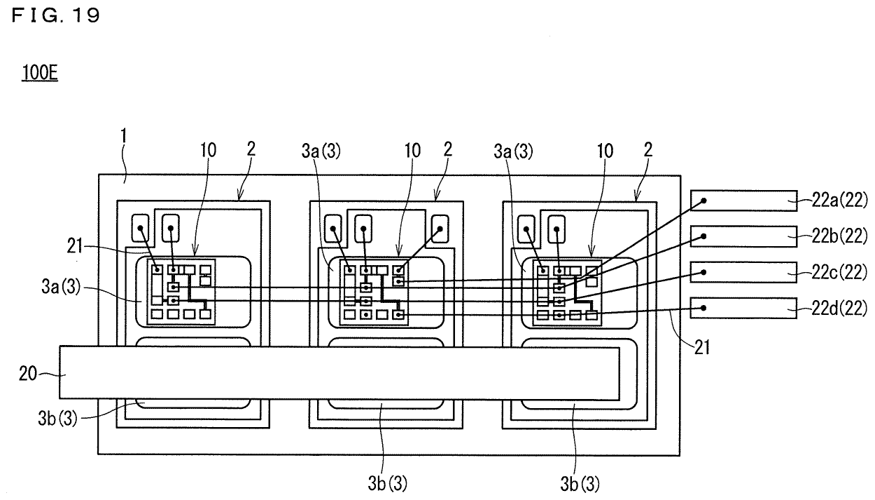

Next, the semiconductor device 100E according to Embodiment 6 will be described. FIG. 19 is a top view of the semiconductor device 100E according to Embodiment 6. In Embodiment 6, the same reference numerals are assigned to the same constituent elements described in Embodiments 1 to 5, and the description thereof will be omitted.

In Embodiment 5, the plurality of wiring elements 10 are disposed on the upper surface of the external electrode 20, in regions in each of which the main terminal electrode 3 in the semiconductor element 2 is disposed.

In contrast, the main terminal electrode 3 that is the surface electrode of each of the semiconductor elements 2 is divided into two regions 3a and 3b as illustrated in FIG. 19 in Embodiment 6. Each of the wiring elements 10 is disposed on the one region 3a, and the external electrode 20 is disposed on the other regions 3b.

Specifically, each of the wiring elements 10 is bonded to the one region 3a in the semiconductor element 2 through a conductive bonding material (not illustrated) such that the wiring element 10 is adjacent to and above the semiconductor element 2. Furthermore, the external electrode 20 is bonded to the other regions 3b in the semiconductor elements 2 through a conductive bonding material (not illustrated).

In each of the wiring elements 10, the resistor 14 that suppresses an oscillation operation of a corresponding one of the semiconductor elements 2 adjacent to and below the wiring element 10, and the diode 13 functioning as a temperature sensor that senses the temperature of the semiconductor element 2 adjacent to and below the wiring element 10 are disposed. The wire pad 12 of each of the wiring elements 10 is disposed to face the wire pad 4 of the semiconductor element 2 adjacent to and below the wiring element 10, and the wire pads 12 are disposed in other portions. The diode 13 of each of the wiring elements 10 is disposed closer to the semiconductor element 2 adjacent to and below the wiring element 10. The wire pad 4 of each of the semiconductor elements 2 is connected through the wire 21 to the wire pad 12 of the wiring element 10 adjacent to and above the semiconductor element 2.

As described above, the semiconductor device 100E according to Embodiment 6 can improve the layout flexibility, sense the temperature of the semiconductor element 2 in consideration of a heat distribution in the semiconductor device 100E, and maximize the effective area of the semiconductor elements 2, similarly to Embodiment 1. Furthermore, a malfunction and a break in the semiconductor device 100E can be suppressed at low cost without requiring disposing a balance resistor in the semiconductor elements 2.

Furthermore, the main terminal electrode 3 of each of the semiconductor elements 2 is divided into the two regions 3a and 3b, each of the wiring elements 10 is disposed on the one region 3a, and the external electrode 20 is disposed on the other regions 3b. This improves the thermal bondability between the wiring elements 10 and the semiconductor elements 2, and improves the precision of sensing the temperature of the semiconductor element 2, more than those in Embodiment 5.

### Modifications of Embodiments 1 to 6

Although Embodiments 1 to 6 describe that the number of the semiconductor elements 2 and the number of the wiring elements 10, 10A, 10B, or 10C are both three, the numbers are not limited to this but should be two or more, and equal numbers.

Although the wiring elements 10, 10A, 10B, or 10C as many as the semiconductor elements 2 are disposed in Embodiments 1 to 6, the wiring elements 10, 10A, 10B, or 10C need not be as many as the semiconductor elements 2, but two or more of the wiring elements 10, 10A, 10B, or 10C may make up the one Si substrate 11.

A capacitor including a silicon oxide film or an insulating interlayer film may be formed in each of the wiring elements 10, 10A, 10B, or 10C in Embodiments 1 to 6. Forming a low-pass filter for the resistor 14 in each of the wiring elements 10, 10A, 10B, or 10C improves the tolerance to switching noise of the semiconductor element 2.

Furthermore, a resistance value of the resistor 14 disposed in each of the wiring elements 10, 10A, 10B, or 10C may be adjustable by laser trimming in Embodiments 1 to 6. This can suppress variations in balance resistors connected between the semiconductor elements 2. When the balance resistors are disposed at gates to prevent gate oscillations at turn off time of parallel operations, a large difference in value between the balance resistors connected to the semiconductor elements 2 increases oscillation risk, but reduces variations in resistance value. This can reduce the oscillation risk, and suppress malfunctions of the semiconductor elements 2.

The protection diodes 24 according to Embodiment 4 can be employed in Embodiments 2 and 3. The desaturation voltage detection output terminal 22e according to Embodiment 2, the high-voltage diodes 19 according to Embodiment 3, and the protection diodes 24 according to Embodiment 4 can be employed in Embodiments 5 and 6.

While the present disclosure is described in detail, the foregoing description is in all aspects illustrative and does not restrict the present disclosure. Thus, numerous modifications that have yet been exemplified will be devised.

Embodiments can be freely combined, and appropriately modified or omitted.

### EXPLANATION OF REFERENCE SIGNS

1 base plate, 2 semiconductor element, 3 main terminal electrode, 3a, 3b region, 4 wire pad, 10, 10A, 10B, 10C wiring element, 12 wire pad, 13 diode, 14 resistor, 19 high-voltage diode, 20 external electrode, 21 wire, 22 control terminal, 22e desaturation voltage detection output terminal, 24 protection diode.

1. A semiconductor device, comprising:
a base plate;
a plurality of semiconductor elements mounted on the base plate, each of the semiconductor elements including a wire pad; and
a plurality of wiring elements disposed adjacent to the respective semiconductor elements on the base plate, each of the wiring elements including a wire pad,
wherein a temperature sensor that senses a temperature of an adjacent one of the semiconductor elements is disposed in each of the wiring elements,
the wire pad of each of the wiring elements is disposed to face the wire pad of the adjacent one of the semiconductor elements,
the temperature sensor of each of the wiring elements is disposed closer to the adjacent one of the semiconductor elements, and
the wire pad of each of the semiconductor elements is connected through a wire to the wire pad of a corresponding one of the wiring elements adjacent to the semiconductor element.

2. The semiconductor device according to claim 1,
wherein a resistor that suppresses an oscillation operation of the adjacent one of the semiconductor elements is further disposed in each of the wiring elements.

3. The semiconductor device according to claim 1, further comprising
at least one control terminal for inputting and outputting a signal on controlling each of the semiconductor elements,
wherein the at least one control terminal comprises a terminal for externally extracting a drain voltage of each of the semiconductor elements.

4. The semiconductor device according to claim 3,
wherein a high-voltage diode that insulates the terminal for externally extracting the drain voltage of the adjacent one of the semiconductor elements is disposed in each of the wiring elements.

5. The semiconductor device according to claim 1,
wherein a protection diode that protects the adjacent one of the semiconductor elements from electrostatic destruction is disposed in each of the wiring elements.

6. A semiconductor device, comprising:
a base plate;
a plurality of semiconductor elements mounted on the base plate, each of the semiconductor elements including a wire pad;
an external electrode disposed on the semiconductor elements and connecting the semiconductor elements; and
a plurality of wiring elements disposed in portions corresponding to the respective semiconductor elements on the external electrode such that each of the wiring elements is adjacent to and above a corresponding one of the semiconductor elements through the external electrode, each of the wiring elements including a wire pad,
wherein in each of the wiring elements, a temperature sensor that senses a temperature of the corresponding one of the semiconductor elements adjacent to and below the wiring element through the external electrode is disposed,
the wire pad of each of the wiring elements is disposed to face the wire pad of the corresponding one of the semiconductor elements adjacent to and below the wiring element through the external electrode,
the temperature sensor of each of the wiring elements is disposed closer to the corresponding one of the semiconductor elements adjacent to and below the wiring element through the external electrode, and
the wire pad of each of the semiconductor elements is connected through a wire to the wire pad of the wiring element adjacent to and above the semiconductor element.

7. The semiconductor device according to claim 6,
wherein in each of the wiring elements, a resistor that suppresses an oscillation operation of the corresponding one of the semiconductor elements adjacent to and below the wiring element through the external electrode is further disposed.

8. A semiconductor device, comprising:
a base plate;
a plurality of semiconductor elements mounted on the base plate, each of the semiconductor elements including a wire pad, and a surface electrode divided into two regions;
an external electrode disposed on the semiconductor elements and connecting the semiconductor elements; and
a plurality of wiring elements each disposed in one of the two regions of a corresponding one of the semiconductor elements such that the wiring element is adjacent to and above the semiconductor element, each of the wiring elements including a wire pad,
wherein the external electrode is connected to the other of the two regions of each of the semiconductor elements,
in each of the wiring elements, a temperature sensor that senses a temperature of the corresponding one of the semiconductor elements adjacent to and below the wiring element is disposed,
the wire pad of each of the wiring elements is disposed to face the wire pad of the corresponding one of the semiconductor elements adjacent to and below the wiring element,
the temperature sensor of each of the wiring elements is disposed closer to the corresponding one of the semiconductor elements adjacent to and below the wiring element, and
the wire pad of each of the semiconductor elements is connected through a wire to the wire pad of the wiring element adjacent to and above the semiconductor element.

9. The semiconductor device according to claim 8,
wherein in each of the wiring elements, a resistor that suppresses an oscillation operation of the corresponding one of the semiconductor elements adjacent to and below the wiring element is further disposed.

10. The semiconductor device according to claim 1,
wherein a capacitor including a silicon oxide film or an insulating interlayer film is formed in each of the wiring elements.

11. The semiconductor device according to claim 2,
wherein a resistance value of the resistor disposed in each of the wiring elements is adjustable by laser trimming.

12. The semiconductor device according to claim 6,
wherein a capacitor including a silicon oxide film or an insulating interlayer film is formed in each of the wiring elements.

13. The semiconductor device according to claim 8,
wherein a capacitor including a silicon oxide film or an insulating interlayer film is formed in each of the wiring elements.

14. The semiconductor device according to claim 7,
wherein a resistance value of the resistor disposed in each of the wiring elements is adjustable by laser trimming.

15. The semiconductor device according to claim 9,
wherein a resistance value of the resistor disposed in each of the wiring elements is adjustable by laser trimming.
